(19) United States
(12) Patent Application Publication
(10) Pub. No.: US 2014/0049310 A1
(43) Pub. Date: Feb. 20, 2014

(54) SEMICONDUCTOR DEVICE, SEMICONDUCTOR SYSTEM, AND MONITORING METHOD THEREOF

(71) Applicant: SK HYNIX INC., Gyeonggi-do (KR)

(72) Inventors: Yong-Suk JOO, Gyeonggi-do (KR); Joo-Hwan CHO, Gyeonggi-do (KR)

(73) Assignee: SK HYNIX INC., Gyeonggi-do (KR)

(21) Appl. No.: 13/709,797

(22) Filed: Dec. 10, 2012

(30) Foreign Application Priority Data
Aug. 17, 2012 (KR) 10-2012-0090069

(51) Int. Cl. H03K 17/00

(52) U.S. Cl. CPC H03K 17/005
USPC 327/407

(57) ABSTRACT

A semiconductor device includes a plurality of oscillation signal generation units configured to output a plurality of oscillation signals whose cycles are adjusted according to a PN ratio, which is a size ratio of a PMOS transistor to an NMOS transistor, and a selection unit configured to selectively output the oscillation signals outputted from the plurality of oscillation signal generation units in response to a test mode signal.

### CROSS-REFERENCE TO RELATED APPLICATIONS

The present application claims priority of Korean Patent Application No. 10-2012-0090069, filed on Aug. 17, 2012, which is incorporated herein by reference in its entirety.

### BACKGROUND

1. Field

Exemplary embodiments of the present invention relate to a semiconductor design, and more particularly, to a semiconductor device which performs a monitoring operation using a ring oscillator delay (ROD), a semiconductor system, and a monitoring method thereof.

2. Description of the Related Art

The characteristics of transistors in a semiconductor device change due to various factors such as voltage, temperature, and process (PVT). Furthermore, transistors arranged in a semiconductor device may show a characteristic different from an initial design due to inconsistencies in gate patterning processes of the transistors or a dose difference in ion-implantation processes to adjust a threshold voltage VT of transistors. This may degrade the performance of a semiconductor product.

In particular, since the semiconductor device requires reduction in size, a minute difference may occur between transistors, which are configured to have the same characteristic in the semiconductor device.

Therefore, it is necessary to implement a device capable of checking the characteristics of the transistors arranged in the semiconductor device. Recently, a scheme has been proposed, which allows monitoring of a semiconductor device by using a ring oscillator delay (ROD) having a characteristic dependent on PVT variation, and allows changing of the size of transistors arranged in the semiconductor device.

FIG. 1 is a block diagram illustrating a conventional semiconductor device.

Referring to FIG. 1, the conventional semiconductor device includes a TMRS decoder 10, an ROD unit 20, and an output unit 30. The TMRS decoder 10 decodes a test execution signal TMRS<0:M> from a test mode register set (TMRS, not illustrated), and generates a ROD enable signal TM_RODEN.

The ROD unit 20 generates a ROD oscillation signal ROD_OUT in response to the ROD enable signal TM_RODEN. The output unit 30 transmits the ROD oscillation signal ROD_OUT as an output signal OUT to a pad in response to the ROD enable signal TM_RODEN.

The ROD unit 20 may include a ring oscillator. The ring oscillator is implemented with a delay chain including a plurality of inverters, and may additionally include a logic gate to receive the ROD enable signal TM_RODEN, for example, a NAND gate. Therefore, the ROD unit 20 performs ring oscillation to generate the ROD oscillation signal ROD_OUT at a frequency determined by a process condition P, an operation voltage V, and an operation temperature T.

FIG. 2 is a timing diagram illustrating the operation of the semiconductor device of FIG. 1.

Referring to FIG. 2, when the ROD enable signal TM_RODEN is activated, the ROD unit 20 of the conventional semiconductor device oscillates the ROD oscillation signal ROD_OUT, and the output unit 30 transmits the ROD oscillation signal ROD_OUT as the output signal OUT to the pad. Accordingly, the output signal OUT may be monitored externally to change the size of transistors arranged in the semiconductor device.

In the configuration of the above-described semiconductor device, when the process is performed in a slow condition, a frequency of the output signal OUT becomes low. In this case, it may be difficult to perform a high-speed operation. On the other hand, when the process is performed in a fast condition, the frequency of the output signal OUT becomes high. In this case, the operation characteristic of the semiconductor device may be improved.

However, when the size ratio (PN ratio) of a PMOS transistor to an NMOS transistor is varied during the process, it may be impossible to monitor the change through the conventional ROD measuring method.

For reference, when a cross point of the output signal OUT deviates from the center level, a timing margin decreases based on the deviation. Therefore, it is very important to constantly maintain the duty cycle of the output signal OUT. Therefore, the PN ratio is controlled to obtain a duty cycle of 50% and the cross point at the center level in the output signal OUT.

Conventionally, since an operation frequency is not high, the duty cycle distortion caused by process variation was not a serious problem. Therefore, the crossing point and the duty cycle may be adjusted by optimizing the PN ratio, without any specific treatment.

However, with the increase of the operation frequency and the decrease of the timing margin, the cross point deviates in the opposite direction, under a condition of an SF (slow NMOS transistor-fast PMOS transistor) or FS (fast NMOS transistor-slow PMOS transistor) process condition, with respect to a TT (typical NMOS transistor-typical PMOS transistor) process condition. Therefore, the cross point may not be adjusted to the center level through the fixed PN ratio. Accordingly, a method for controlling the PN ratio in the SF and FS process conditions has been proposed.

In the configuration of the conventional semiconductor device, however, although the PN ratio is changed from the TT state and the FS state, the ROD measurement value is not changed. That is, only the ROD result value having one pattern is used to measure the characteristics of transistors in the semiconductor device. Therefore, although the PN ratio is changed, the ROD result value may not reflect the change.

### SUMMARY

Exemplary embodiments of the present invention are directed to schemes which generate an output signal by reflecting a PN ratio based on change in characteristics of transistor, when the variables of elements required in a semiconductor device (for example, transistors size) are changed using a ROD having a characteristic dependent on PVT variation, and monitors the semiconductor device using the output signal, thereby securing a stable operation.

In accordance with an embodiment of the present invention, a semiconductor device includes a plurality of oscillation signal generation units configured to output a plurality of oscillation signals whose cycles are adjusted according to a PN ratio which is a size ratio of a PMOS transistor to an NMOS transistor, and a selection unit configured to selectively output the oscillation signals outputted from the plurality of oscillation signal generation units in response to a test mode signal.

In accordance with another embodiment of the present invention, a semiconductor device includes a first oscillation signal generation unit configured to generate a first oscillation signal reflecting a typical process condition in response to a first control signal. a second oscillation signal generation unit configured to generate a second oscillation signal reflecting a first process condition in response to a second control signal, a third oscillation signal generation unit configured to generate a third oscillation signal reflecting a second process condition in response to a third control signal and a selection unit configured to selectively output the first to third oscillation signals in response to the first to third control signals.

In accordance with yet another embodiment of the present invention, a semiconductor system includes a semiconductor device configured to sequentially output a plurality of oscillation signals whose cycles are adjusted according to a PN ratio, which is a size ratio of a PMOS transistor to an NMOS transistor, during a test mode operation, and a monitoring device configured to receive the sequentially-outputted oscillation signals and monitor a process condition of the semiconductor device.

In accordance with still another embodiment of the present invention, a monitoring method of a semiconductor device includes generating a first oscillation signal reflecting a typical process condition in response to a first control signal, generating a second oscillation signal reflecting a first process condition in response to a second control signal, generating a third oscillation signal reflecting a second process condition in response to a third control signal, and selectively outputting the first to third oscillation signals.

### BRIEF DESCRIPTION OF THE DRAWINGS

FIG. 1 is a block diagram illustrating a conventional semiconductor device.

FIG. 2 is a timing diagram illustrating the operation of the semiconductor device of FIG. 1.

FIG. 3 is a block diagram illustrating a semiconductor device in accordance with an embodiment of the present invention.

FIGS. 4A to 4C are timing diagrams illustrating output waveforms of first to third oscillation signal generation units based on process condition change in accordance with the embodiment of the present invention.

FIG. 5 is a block diagram illustrating a semiconductor system in accordance with another embodiment of the present invention.

FIG. 6 is a timing diagram illustrating a monitoring operation in accordance with the embodiment of the present invention.

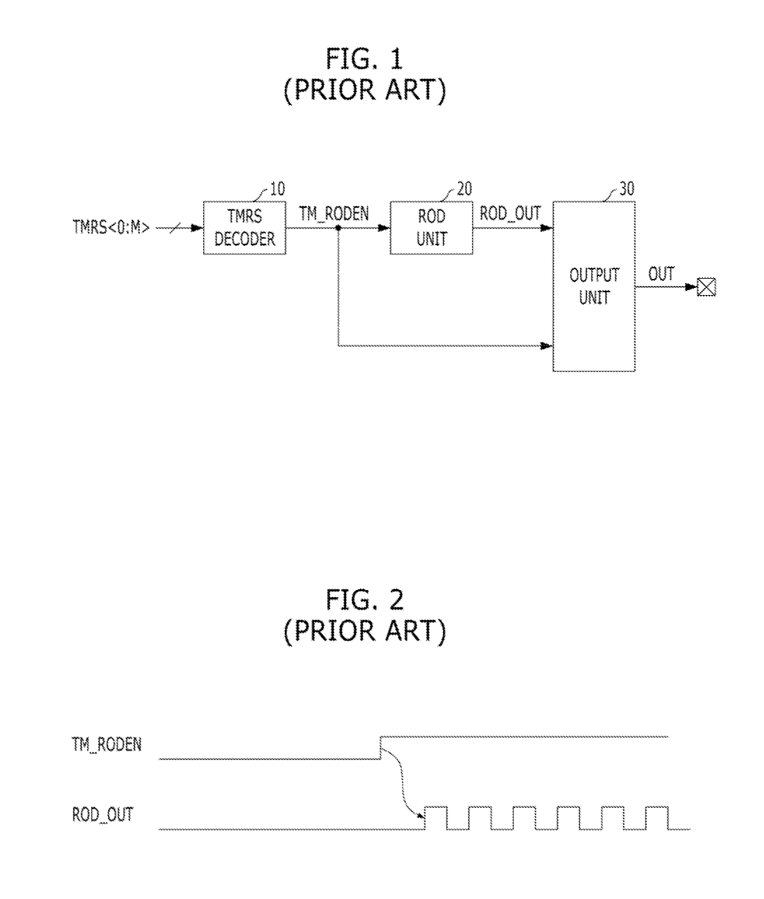

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled the art. Throughout the disclosure, like reference numerals refer to like parts throughout the various figures and embodiments of the present invention.

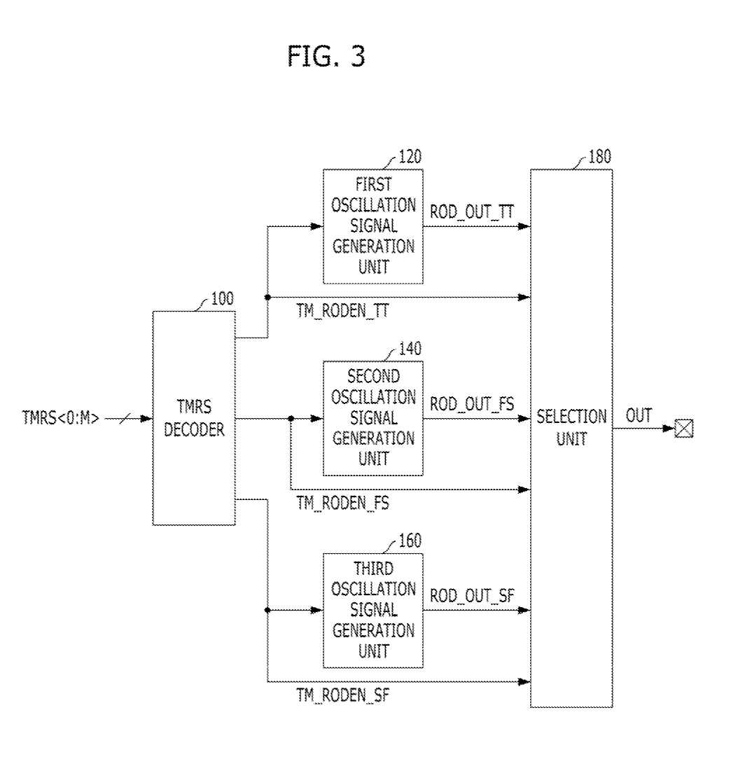

FIG. 3 is a block diagram illustrating a semiconductor device in accordance with an embodiment of the present invention.

Referring to FIG. 3, the semiconductor device includes a plurality of oscillation signal generation units 120, 140, and 160, and a selection unit 180.

The plurality of oscillation signal generation units 120, 140, and 160 are configured to output a plurality of oscillation signals ROD_OUT_TT, ROD_OUT_FS, and ROD_OUT_SF, respectively, of which the cycles are controlled according to a PN ratio, which is a size ratio of a PMOS transistor to an NMOS transistor.

The selection unit 180 is configured to selectively output the plurality of oscillation signals ROD_OUT_TT, ROD_OUT_FS, and ROD_OUT_SF, which are outputted from the respective oscillation signal generation units 120, 140, and 160, as an output signal OUT in response to a plurality of test mode signals TM_RODEN_TT, TM_RODEN_FS, and TM_RODEN_SF, respectively.

The semiconductor device may further include a TMRS decoder 100 and an output pad. The TMRS decoder 100 is configured to receive a test execution signal TMRS<0:M> from a test mode register set (TMRS), and decode the received signal to generate the plurality of test mode signals TM_RODEN_TT, TM_RODEN_FS, and TM_RODEN_SF. The output pad is configured to output the output signal OUT outputted from the selection unit 180 to the outside.

Among the plurality of oscillation signal generation units 120, 140, and 160, the oscillation signal generation unit 120 is configured to generate the first oscillation signal ROD_OUT_TT reflecting a typical process condition in response to the first test mode signal TM_RODEN_TT. The second oscillation signal generation unit 140 is configured to generate the second oscillation signal ROD_OUT_FS reflecting a first process condition in response to the second test mode signal TM_RODEN_FS. The third oscillation signal generation unit 160 is configured to generate the third oscillation signal ROD_OUT_SF reflecting a second process condition in response to the third test mode signal TM_RODEN_SF.

Each of the first to third oscillation signal generation units 120, 140, and 160 may include a ring oscillator delay (ROD). The ROD is implemented with a delay chain including a plurality of inverters. The ROD may further include a logic gate to receive the corresponding test mode signal, for example, a NAND gate. The ROD generates an oscillation signal at a cycle (or frequency) affected by a process condition P, an operation voltage V, and an operation temperature T.

The semiconductor device in accordance with the embodiment of the present invention includes the first oscillation signal generation unit 120 to generate the first oscillation signal ROD_OUT_TT by reflecting the typical process condition. In addition, the semiconductor device may include the second oscillation signal generation unit 140 to generate the second oscillation signal by reflecting the first process condition in which the PN ratio is larger compared to the PN ratio in the typical process condition. The semiconductor device may further include the third oscillation signal generation unit 160 to generate the third oscillation signal by reflecting the second process condition in which the PN ratio is smaller compared to the PN ratio in the typical process condition. Therefore, the semiconductor device in accordance with the embodiment of the present invention may generate the plurality of oscillation signals in which the PN ratio as well as the PVT variation in which the semiconductor device was fabricated is considered.

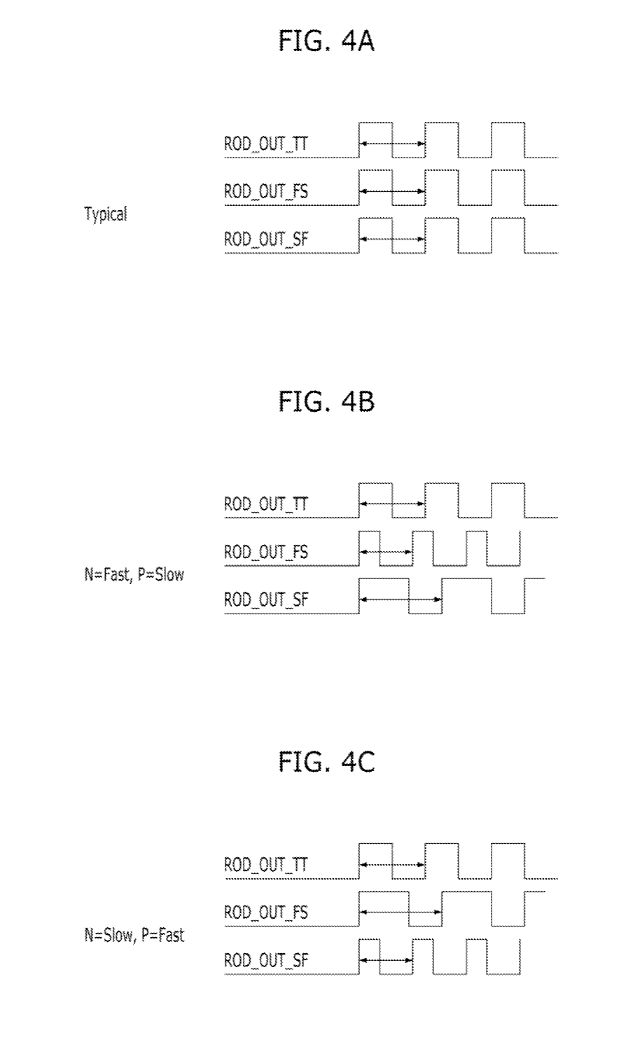

FIGS. 4A to 4C are timing diagrams illustrating output waveforms of the first to third oscillation signal generation units 120, 140, and 160 based on the process condition change.

Referring to FIG. 4A, when the process condition is not changed, that is, under the typical process condition, the first to third oscillation signals ROD_OUT_ROD_OUT_FS, and ROD_OUT_SF outputted from the first to third oscillation signal generation units 120, 140, and 160 are outputted at the same cycle.

Referring to FIG. 4B, however, when the process condition becomes an FS condition (fast NMOS transistor-slow PMOS transistor), the cycles of the first to third oscillation signals ROD_OUT_TT, ROD_OUT_FS, and ROD_OUT_SF become different. Specifically, the second oscillation signal ROD_OUT_FS has the smallest cycle, and the third oscillation signal ROD_OUT_SF has the largest cycle. Referring to FIG. 4C, when the process condition becomes an SF condition (slow NMOS transistor-fast PMOS transistor), the cycles of the first to third oscillation signals ROD_OUT_TT, ROD_OUT_FS, and ROD_OUT_SF become different. Specifically, the third oscillation signal ROD_OUT_SF has the smallest cycle, and the second oscillation signal ROD_OUT_FS has the largest cycle. In accordance with the embodiment of the present invention, the cycles of the first to third oscillation signals ROD_OUT_TT, ROD_OUT_FS, and ROD_OUT_SF may be monitored to determine a current process condition. Based on the process condition, it is possible to analyze and estimate the characteristic of the semiconductor device.

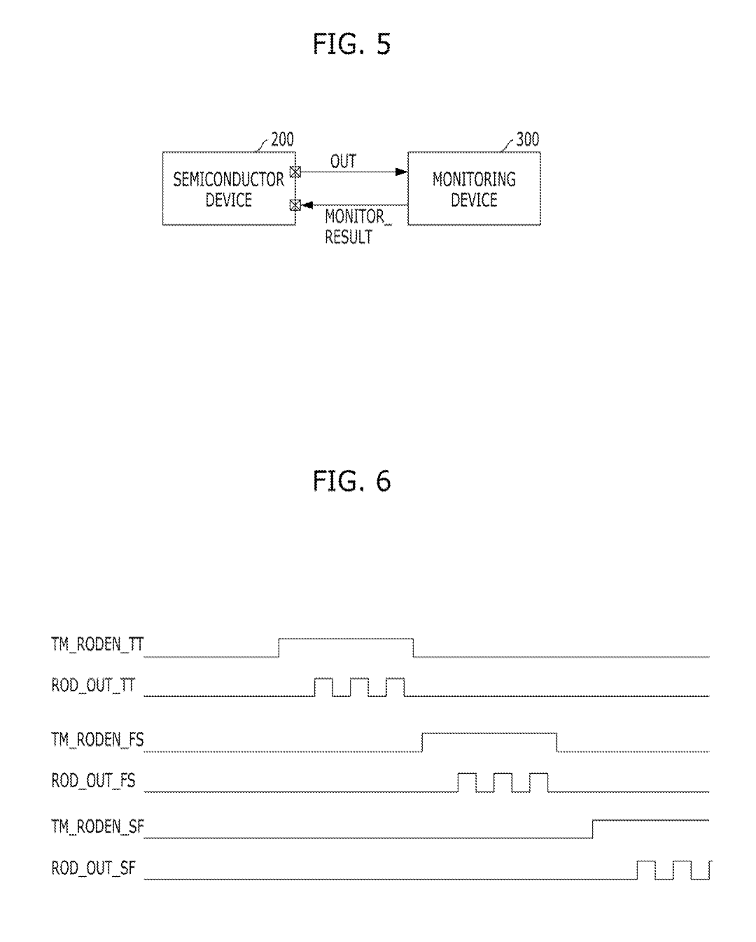

FIG. 5 is a block diagram of a semiconductor system in accordance with another embodiment of the present invention.

Referring to FIG. 5, the semiconductor system in accordance with the embodiment of the present invention includes a semiconductor device 200 and a monitoring device 300. The semiconductor device 200 is configured to sequentially output the plurality of oscillation signals ROD_OUT_TT, ROD_OUT_FS, and ROD_OUT_SF whose cycles are adjusted according to a size ratio of a PMOS transistor to an NMOS transistor (PN ratio), in response to the plurality of test mode signals TM_RODEN_TT, TM_RODEN_FS, and TM_RODEN_SF. The monitoring device 300 is configured to receive the sequentially outputted oscillation signals ROD_OUT_TT, ROD_OUT_FS, and ROD_OUT_SF and monitor the process condition of the semiconductor device 200.

The semiconductor device 200 may receive a monitoring result MONITOR_RESULT transmitted from the monitoring device 300, and change the size of transistors arranged therein in response to the monitoring result MONITOR_RESULT.

As illustrated in FIG. 3, the semiconductor device 200 may include the TMRS decoder 100, the plurality of oscillation signal generation units 120, 140, and 160, the selection section 180, and the output pad.

The TMRS decoder 100 is configured to receive the test execution signal TMRS<0:M> from the TMRS and decode the received signal to generate the plurality of test mode signals TM_RODEN_TT, TM_RODEN_FS and TM_RODEN_FS.

The plurality of oscillation signal generation units 120, 140, and 160 are configured to output the plurality of oscillation signals ROD_OUT_TT, ROD_OUT_FS, and ROD_OUT_SF whose cycles are adjusted according to a size ratio of an PMOS transistor and an NMOS transistor, i.e., the PN ratio, in response to the plurality of test mode signals RM_RODEN_TT, TM_RODEN_FS, and TM_RODEN_FS.

The selection unit 180 is configured to selectively output the plurality of oscillation signals ROD_OUT_TT, ROD_OUT_FS, and ROD_OUT_SF outputted from the respective oscillation signal generation units 120, 140, and 160 in response to the plurality of test mode signals TM_RODEN_TT, TM_RODEN_FS, and TM_RODEN_SF. The output pad is configured to output an output signal OUT of the select unit 180 to the monitoring device 300.

Therefore, in the semiconductor system in accordance with the embodiment of the present invention, when the semiconductor device 200 generates and outputs the plurality of oscillation signals in which the PN ratio as well as the PVT variation are considered, the monitoring device 300 may monitor the process condition of the semiconductor device 200 from various angles, and the semiconductor device 200 may receive the monitoring result and change the characteristics of the internal transistors. Therefore, the semiconductor system may secure a stable operation even though the process condition is not typical.

Hereafter, referring to FIGS. 3 to 6, a monitoring method of the semiconductor device and the semiconductor system in accordance with the embodiment of the present invention will be described.

FIG. 6 is a timing diagram illustrating the monitoring operation in accordance with the embodiment of the present invention.

Referring to FIG. 6, the TMRS decoder 100 of the semiconductor device 200 decodes the test execution signal TMRS<0:M> outputted from the test mode register set TMRS and sequentially activates the first to third test mode signals TM_RODEN_TT, TM_RODEN_FS, and TM_RODEN_SF.

The first oscillation signal generation unit 120 of the semiconductor device 200 generates the first oscillation signal ROD_OUT_TT reflecting the typical process condition, when the first test mode signal TM_RODEN_TT is activated. Then, the second oscillation signal generation unit 140 of the semiconductor device 200 generates the second oscillation signal ROD_OUT_FS reflecting the first process condition, when the second test mode signal TM_RODEN_FS is activated. Finally, the third oscillation signal generation unit 160 of the semiconductor device 200 generates the third oscillation signal ROD_OUT_SF reflecting the second process condition, when the third test mode signal TM_RODEN_SF is activated.

The selection unit 180 of the semiconductor device 200 sequentially outputs the first to third oscillation signals ROD_OUT_TT, ROD_OUT_FS, and ROD_OUT_SF as the output signals OUT in response to the first to third test mode signals TM_RODEN_TT, TM_RODEN_FS, and TM_RODEN_SF.

The monitoring device 300 receives the first to third oscillation signals ROD_OUT_TT, ROD_OUT_FS, and ROD_OUT_SF monitors the process condition of the semiconductor device from the received signals and transmits the monitoring result MONITOR_RESULT to the semiconductor device.

The semiconductor device 200 may change the size transistors provided therein in response to the monitoring result.

Under the typical process condition as illustrated in FIG. 4A, the first to third oscillation signals ROD_OUT_TT, ROD_OUT_FS, and ROD_OUT_SF outputted from the first to third oscillation signal generation units 120, 140, and 160 are outputted at the same cycle. Therefore, the size of the transistors does not need to be adjusted.

However, when the process condition becomes the FS condition or SF condition as illustrated in FIG. 4B or 4C, the cycles of the first to third oscillation signals ROD_OUT_TT, ROD_OUT_FS, and in ROD_OUT_SF are adjusted. The external test device analyzes the first to third oscillation signals ROD_OUT_TT, ROD_OUT_FS, and ROD_OUT_SF whose cycles are adjusted, and transmits the monitoring result to the semiconductor device. Accordingly, the semiconductor device may adjust the size of the PMOS transistor or NMOS transistor.

As described above, when the variables of necessary elements inside the semiconductor device (for example, transistor size) are changed by using the ROD monitoring device having a characteristic dependent on the PVT variation, the monitoring method in accordance with the embodiment of the present invention monitors the plurality of oscillation signals whose cycles are adjusted, according to the size ratio of the PMOS transistor and the NMOS transistor, i.e., the PN ratio, thereby determining the current process state of the semiconductor device. Furthermore, the PN ratio based on the variation of transistor characteristics may be reflected to monitor the process state of the semiconductor device. Therefore, it is possible to easily analyze a malfunction of the memory device.

Furthermore, various process conditions may be reflected to monitor the process condition of the semiconductor device. Therefore, it may be possible to secure a stable operation even though a process condition is not typical.

While the present invention has been described with respect to the specific embodiments, it will be apparent to those skilled in the art that various changes and modifications may be made without departing from the spirit and scope of the invention as defined in the following claims.

What is claimed is:

1. A semiconductor device comprising:
a plurality of oscillation signal generation units configured to output a plurality of oscillation signals whose cycles are adjusted according to a PN ratio, which is a size ratio of a PMOS transistor to an NMOS transistor; and
a selection unit configured to selectively output the oscillation signals outputted from the plurality of oscillation signal generation units in response to a test mode signal.

2. The semiconductor device of claim 1 further comprising a decoder configured to generate the test mode signal in response to a test execution signal outputted from a test mode register set.

3. The semiconductor device of claim 1, further comprising an output pad configured to output an output signal from the selection unit.

4. The semiconductor device of claim 1, wherein the plurality of oscillation signal generation units comprise ring oscillator delays each having different oscillation frequency according to the PN ratio.

5. A semiconductor device comprising:
a first oscillation signal generation unit configured to generate a first oscillation signal reflecting a typical process condition in response to a first control signal;
a second oscillation signal generation unit configured to generate a second oscillation signal reflecting a first process condition in response to a second control signal;
a third oscillation signal generation unit configured to generate a third oscillation signal reflecting a second process condition in response to a third control signal; and
a selection unit configured to selectively output the first to third oscillation signals in response to the first to third control signals.

6. The semiconductor device of claim 5, further comprising a decoder configured to generate the first to third control signals by decoding a test execution signal outputted from a test mode register set.

7. The semiconductor device of claim 5, further comprising an output pad configured to output an output signal from the selection unit.

8. The semiconductor device of claim 5, wherein the first to third control signals are sequentially activated.

9. The semiconductor device of claim 5, wherein the first to third oscillation signal generation units comprise ring oscillator delays each having a different oscillation frequency according to a PN ratio.

10. The semiconductor device of claim 5, wherein the first process condition indicates a case in which a PN ratio is larger compared to the PN ratio in the typical process condition, and wherein the second process condition indicates a case in which the PN ratio is smaller compared to the PN ratio in the typical process condition.

11. A semiconductor system comprising:
a semiconductor device configured to sequentially output a plurality of oscillation signals whose cycles are adjusted according to a PN ratio, which is a size ratio of a PMOS transistor to an NMOS transistor, during a test mode operation; and
a monitoring device configured to receive the sequentially-outputted oscillation signals and monitor a process condition of the semiconductor device.

12. The semiconductor system of claim 11, wherein the semiconductor device receives a monitoring result transmitted from the monitoring device, and changes the size of the transistors in response to the monitoring result.

13. The semiconductor system of claim 11, wherein the semiconductor device comprises:
a decoder configured to receive a test execution signal and decode the received signal to generate a plurality of test mode signals;
a plurality of oscillation signal generation units configured to output the plurality of oscillation signals whose cycles are adjusted according to the PN ratio, in response to the plurality of test mode signal's;
a selection unit configured to selectively output the plurality of oscillation signals in response to the plurality of test mode signals; and
an output pad configured to output an output signal from the selection unit to the monitoring device.

14. The semiconductor system of claim 11, wherein the plurality of oscillation signal generation units comprise:
a first oscillation signal generation unit configured to generate a first oscillation signal reflecting a typical process condition in response to a first test mode signal;
a second oscillation signal generation unit configured to generate a second oscillation signal in which a process condition having a larger PN ratio than the typical process condition is reflected, in response to a second test mode signal; and
a third oscillation signal generation unit configured to generate a third oscillation signal in which a process condition having a smaller PN ratio than the typical process condition is reflected, in response to a third test mode signal.

15. A monitoring method of a semiconductor device, comprising:
generating a first oscillation signal reflecting a typical process condition in response to a first control signal;
generating a second oscillation signal reflecting a first process condition in response to a second control signal;
generating a third oscillation signal reflecting a second process condition in response to a third control signal; and
selectively outputting the first to third oscillation signals.

16. The monitoring method of claim 15, further comprising generating the first to third control signals by decoding a test execution signal outputted from a test mode register set.

17. The monitoring method of claim 15, wherein the first to third control signals are sequentially activated, and wherein the first to third oscillation signals are sequentially outputted in response to the first to third control signals.

18. The monitoring method of claim 15, wherein the first process condition indicates a case in which a PN ratio is larger compared to the PN ratio in the typical process condition.

19. The monitoring method of claim 15, wherein the second process condition indicates a case in which a PN ratio is smaller compared to the PN ratio in the typical process condition.

20. The monitoring method of claim 15, further comprising receiving a monitoring result transmitted from a monitoring device, and changing the size of the transistors in response to the monitoring result.
